(19) United States
(12) Patent Application Publication
(10) Pub. No.: US 2018/0062555 A1
(43) Pub. Date: Mar. 1, 2018

(54) BOOSTER CONTROL DEVICE AND METHOD OF CONTROLLING VOLTAGE OF BOOSTER CONTROL DEVICE

(71) Applicant: Komatsu Ltd., Tokyo (JP)

(72) Inventors: Tomohiko Sagawa, Hiratsuka-shi (JP); Atsushi Moki, Fujisawa-shi (JP)

(21) Appl. No.: 15/324,336

(22) PCT Filed: Aug. 26, 2016
(86) PCT No.: PCT/JP2016/075047

§ 371 Date: Jan. 6, 2017

(51) Int. Cl. H02P 27/06; H03G 1/00; H02M 3/335

(52) U.S. Cl. CPC H02P 27/06; H02M 3/33569; H03G 1/0094

(57) ABSTRACT

A booster control device includes an output voltage detection unit that detects output voltage of a booster which changes the output voltage according to a phase difference; a storage battery voltage detection unit that detects storage battery voltage; and a booster control unit that performs feedback control on the output voltage of the booster in order for a difference between an output voltage command value to the booster and detected output voltage to be equal to zero. Further, the booster control unit includes a gain control unit that corrects a control gain according to the storage battery voltage on the basis of storage battery voltage dependency of an input-output characteristic representing booster output with respect to a phase difference of the booster, in order for the booster output to have the control gain uniquely determined by the phase difference and outputs a control phase difference to the booster.

### FIELD

The present invention relates to a booster control device capable of ensuring stability of control while inhibiting degradation in control responsiveness of a booster, and a method of controlling voltage applied to the booster control device.

### BACKGROUND

A hybrid work vehicle equipped with an engine and a rotating electrical machinery as driving sources includes a storage battery such as a battery that supplies a power source to the rotating electrical machinery while storing power generated by the rotating electrical machinery. It is common for the hybrid work vehicle having such configuration that the rotating electrical machinery is subjected to voltage control by focusing on efficiency of an inverter that drives the rotating electrical machinery.

Patent Literature 1 discloses a booster that is a transformer-coupled DC-DC converter in which two bridge circuits each having a plurality of switching elements are coupled to each other by a transformer, is provided between an inverter connected to a rotating electrical machinery and a storage battery supplying power to the rotating electrical machinery, and changes output voltage according to a phase difference between voltages output by each of the bridge circuits.

### CITATION LIST

### Patent Literature

Patent Literature 1: Japanese Laid-open Patent Publication No. 2015-6037

### SUMMARY

### Technical Problem

Now, a booster control unit controlling the aforementioned booster performs feedback control on the output voltage of the booster such that an error between an output voltage command value for the booster and a detected output voltage detected by an output voltage detection unit detecting the output voltage of the booster equals zero. A PI control unit of the booster control unit has a hardware configuration using a resistor and a capacitor, so that a control gain is fixed on the basis of an input-output characteristic representing booster output with respect to a phase difference input to the booster.

However, the input-output characteristic of the aforementioned transformer-coupled booster varies depending on the magnitude of capacitor voltage. Specifically, the input-output characteristic has a capacitor voltage dependency that a change in the booster output with respect to the phase difference, namely a gain, is larger when the capacitor voltage is high than when the capacitor voltage is low. As a result, when the control gain is set on the basis of the time when the capacitor voltage is high, for example, the control gain when the capacitor voltage is low is small so that followability with respect to the output voltage command value is degraded. On the contrary, when the control gain is set on the basis of the time when the capacitor voltage is low, the control gain when the capacitor voltage is high becomes excessively large to possibly cause hunting or oscillation.

Note that the conventional booster control unit having the hardware configuration requires time and effort to change the control gain of the PI control unit.

The present invention has been made in view of the aforementioned problems, where an object of the present invention is to provide a booster control device capable of ensuring stability of control while inhibiting degradation in control responsiveness of a booster, and a method of controlling voltage applied to the booster control device.

### Solution to Problem

To resolve the above problem and attain the object, a booster control device according to the present invention includes an output voltage detection unit that detects output voltage of a booster which is a transformer-coupled DC-DC converter in which two bridge circuits each having a plurality of switching elements are coupled to each other by a transformer, is provided between an inverter connected to a rotating electrical machinery and a storage battery supplying power to the rotating electrical machinery, and changes the output voltage according to a phase difference between voltages output by the bridge circuits; a storage battery voltage detection unit that detects storage battery voltage across the storage battery; and a booster control unit that performs feedback control on the output voltage of the booster in order for a difference between an output voltage command value to the booster and detected output voltage detected by the output voltage detection unit to be equal to zero. Further, the booster control unit includes a gain control unit that corrects a control gain according to the storage battery voltage detected by the storage battery voltage detection unit on the basis of storage battery voltage dependency of an input-output characteristic representing booster output with respect to a phase difference of the booster, in order for the booster output to have the control gain uniquely determined by the phase difference independently of the storage battery voltage and outputs a control phase difference to the booster.

In the booster control device according to the above invention, the booster control unit includes a non-linearity correction unit that corrects the control phase difference in order for non-linearity of the input-output characteristic representing the booster output with respect to the phase difference of the booster to be linear.

In the booster control device according to the above invention, the booster control unit includes an output restriction unit that restricts a variation in output of the control phase difference to a predetermined value or less in each control period.

in the booster control device according to the above invention, the storage battery is a capacitor.

A method of controlling voltage of a booster control device according to the present invention including: an output voltage detection unit that detects output voltage of a booster which is a transformer-coupled DC-DC converter in which two bridge circuits each having a plurality of switching elements are coupled to each other by a transformer, is provided between an inverter connected to a rotating electrical machinery and a storage battery supplying power to the rotating electrical machinery, and changes the output voltage according to a phase difference between voltages output by the bridge circuits; a storage battery voltage detection unit that detects storage battery voltage across the storage battery; and a booster control unit that performs feedback control on the output voltage of the booster in order for a difference between an output voltage command value to the booster and detected output voltage detected by the output voltage detection unit to be equal to zero, the booster control unit corrects a control gain according to the storage battery voltage detected by the storage battery voltage detection unit on the basis of storage battery voltage dependency of an input-output characteristic representing booster output with respect to a phase difference of the booster, in order for the booster output to have the control gain uniquely determined by the phase difference independently of the storage battery voltage and outputs a control phase difference to the booster.

The method of controlling voltage of a booster control device according to the above invention, the booster control unit corrects the control phase difference in order for non-linearity of the input-output characteristic representing the booster output with respect to the phase difference of the booster to be linear.

The method of controlling voltage of a booster control device according to the above invention, the booster control unit restricts a variation in output of the control phase difference to a predetermined value or less in each control period.

According to the present invention, the booster control unit corrects a control gain according to the storage battery voltage detected by the storage battery voltage detection unit on the basis of storage battery voltage dependency of an input-output characteristic representing booster output with respect to a phase difference of the booster, in order for the booster output to have the control gain uniquely determined by the phase difference independently of the storage battery voltage and outputs a control phase difference to the booster, it becomes possible to secure the stability of the control.

### BRIEF DESCRIPTION OF DRAWINGS

FIG. 1 is a perspective view illustrating an overall configuration of a hybrid excavator equipped with a voltage control device that is an embodiment of the present invention.

FIG. 2 is a block diagram illustrating a device configuration of the hybrid excavator illustrated in FIG. 1.

FIG. 3 is a diagram illustrating a configuration of a booster.

FIG. 4 is a timing chart provided to describe an operation of the booster.

FIG. 5 is a graph illustrating a relationship between booster output and a phase difference.

FIG. 6 is a diagram illustrating a configuration of each of a booster control unit included in a hybrid controller and the booster.

FIG. 7 is a block diagram including a detailed configuration of a phase difference control unit.

FIG. 8 is a graph illustrating an example of an input-output characteristic representing the booster output with respect to the phase difference of the booster.

FIG. 9 is a graph illustrating a correction table referenced by a gain control unit and indicating a correction characteristic of each of a proportional gain and an integral gain with respect to capacitor voltage.

FIG. 10 is a diagram illustrating an effect when a gain correction is performed by the capacitor voltage.

FIG. 11 is a graph illustrating non-linearity of the input-output characteristic representing the booster output with respect to the phase difference of the booster.

FIG. 12 is a graph illustrating an example of a correction table used to correct a change in the gain caused by the non-linearity of the input-output characteristic.

FIG. 13 is a diagram illustrating an effect when a gain correction is performed by a non-linearity correction unit.

FIG. 14 is a diagram illustrating an effect when an output restriction is imposed by an output restriction unit.

### DESCRIPTION OF EMBODIMENTS

An embodiment of the present invention will now be described with reference to the drawings.

(Overall Configuration of Hybrid Excavator Equipped with Voltage Control Device)

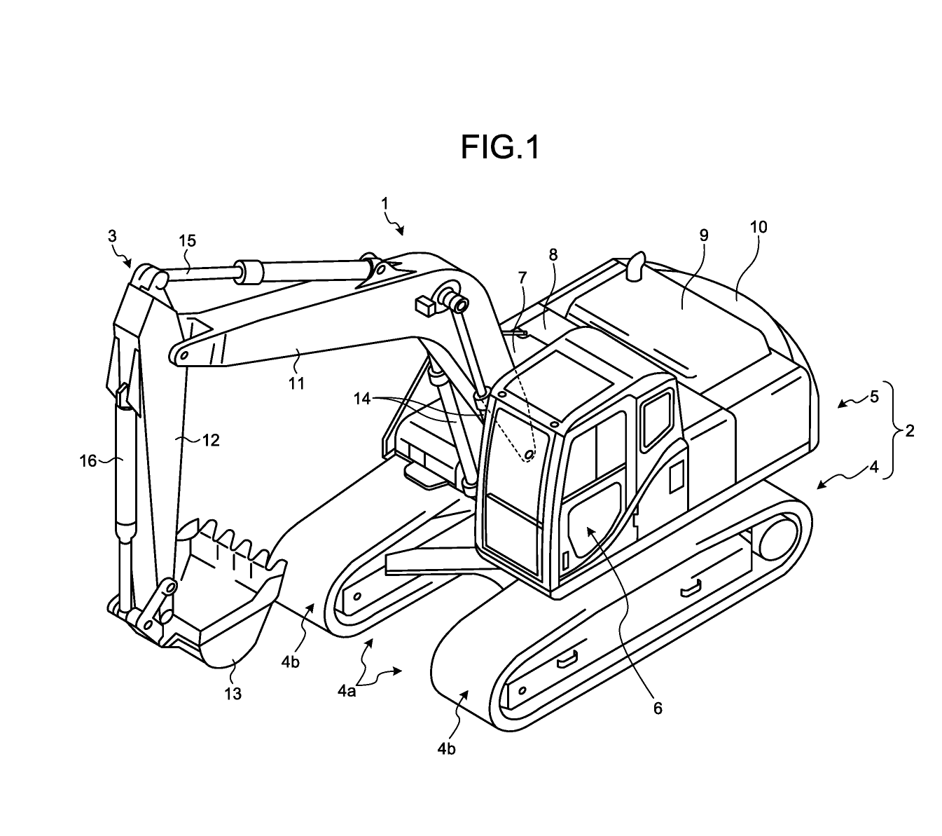

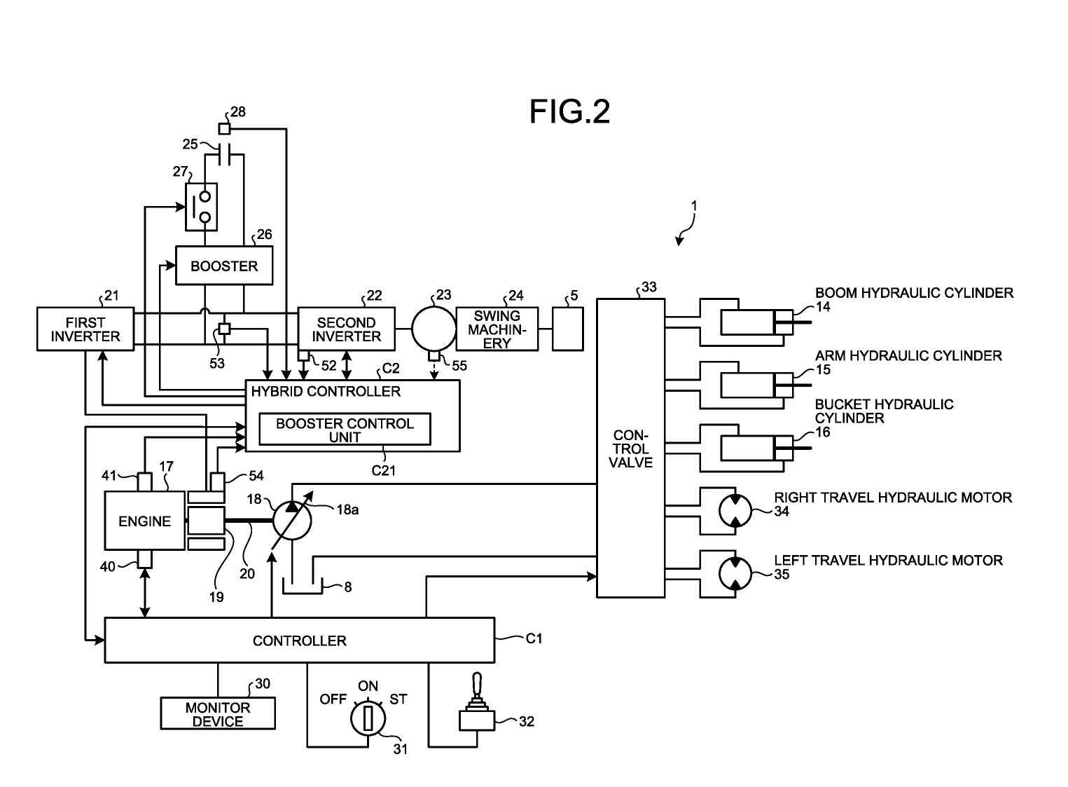

FIG. 1 is a perspective view illustrating an overall configuration of a hybrid excavator 1 equipped with a voltage control device that is an embodiment of the present invention. FIG. 2 is a block diagram illustrating a device configuration of the hybrid excavator 1 illustrated in FIG. 1.

The hybrid excavator 1 serving as a hybrid work machine includes a vehicle body 2 and work equipment 3. The vehicle body 2 includes a lower traveling body 4 and an upper swing body 5. The lower traveling body 4 has a pair of travel units 4a. Each travel unit 4a has a crawler belt 4b. Each travel unit 4a is configured such that the crawler belt 4b is driven by rotation of a right travel hydraulic motor 34 and a left travel hydraulic motor 35 illustrated in FIG. 2 to cause the hybrid excavator 1 to travel.

The upper swing body 5 is provided on top of the lower traveling body 4. The upper swing body 5 swings with respect to the lower traveling body 4. The upper swing body 5 includes a swing motor 23 serving as a rotating electrical machinery in order swing itself. The swing motor 23 is connected to a drive shaft of swing machinery 24 (a reduction device). Torque of the swing motor 23 is transmitted through the swing machinery 24, so that the transmitted torque is transmitted to the upper swing body 5 through a swing pinion and a swing circle that are not illustrated to swing the upper swing body 5.

The upper swing body 5 is provided with an operator cab 6. The upper swing body 5 also includes a fuel tank 7, a hydraulic fluid tank 8, an engine room 9, and a counter weight 10. The fuel tank 7 stores fuel used to drive an engine 17. The hydraulic fluid tank 8 stores hydraulic fluid that is ejected from a hydraulic pump 18 to hydraulic equipment such as a hydraulic cylinder including a boom hydraulic cylinder 14, an arm hydraulic cylinder 15 and a bucket hydraulic cylinder 16 as well as a hydraulic motor (hydraulic actuator) including the right travel hydraulic motor 34 and the left travel hydraulic motor 35. Various equipment including the engine 17, the hydraulic pump 18, a generator motor 19 as a rotating electrical machinery, and a capacitor 25 as a storage battery are stored in the engine room 9. The counter weight 10 is arranged behind the engine room 9.

The work equipment 3 is mounted to the center of a front part of the upper swing body 5 and includes a boom 11, an arm 12, a bucket 13, the boom hydraulic cylinder 14, the arm hydraulic cylinder 15, and the bucket hydraulic cylinder 16. A base end of the boom 11 is turnably connected to the upper swing body 5. A tip end opposite to the base end of the boom 11 is turnably connected to a base end of the arm 12. The bucket 13 is turnably connected to a tip end opposite to the base end of the arm 12. The bucket 13 is also connected to the bucket hydraulic cylinder 16 through a link. The boom hydraulic cylinder 14, the arm hydraulic cylinder 15 and the bucket hydraulic cylinder 16 are the hydraulic cylinders (hydraulic actuators) that extend/contract by the hydraulic fluid ejected from the hydraulic pump 18. The boom hydraulic cylinder 14 turns the boom 11. The arm hydraulic cylinder 15 turns the arm 12. The bucket hydraulic cylinder 16 turns the bucket 13.

As illustrated in FIG. 2, the hybrid excavator 1 includes the engine 17, the hydraulic pump 18, and the generator motor 19. A diesel engine is used as the engine 17, while a variable displacement hydraulic pump is used as the hydraulic pump 18. The hydraulic pump 18 is a swash plate hydraulic pump that changes a tilt angle of a swash plate 18a to change the pump capacity, for example, but is not limited to such a pump. The engine 17 includes a speed sensor 41 that detects speed (engine speed per unit time) of the engine 17. A signal indicating the speed of the engine 17 detected by the speed sensor 41 is input to a hybrid controller C2. The speed sensor 41 is operated with power supplied from a battery not illustrated, and detects the speed of the engine 17 as long as a key switch 31 (to be described) is operated to an on (ON) position or a start (ST) position.

The hydraulic pump 18 and the generator motor 19 are mechanically connected to a drive shaft 20 of the engine 17 and are driven when the engine 17 is driven. A hydraulic drive system includes a control valve 33, the boom hydraulic cylinder 14, the arm hydraulic cylinder 15, the bucket hydraulic cylinder 16, the right travel hydraulic motor 34 and the left travel hydraulic motor 35, where these hydraulic equipment are driven when the hydraulic pump 18 supplies the hydraulic fluid to the hydraulic drive system. Note that the control valve 33 is a flow direction control valve that moves a spool (not illustrated) according to a direction in which a control lever 32 is operated, regulates the direction of flow of the hydraulic fluid to each hydraulic actuator, and supplies the hydraulic fluid corresponding to the amount the control lever 32 is operated to the hydraulic actuator such as the boom hydraulic cylinder 14, the arm hydraulic cylinder 15, the bucket hydraulic cylinder 16, the right travel hydraulic motor 34 or the left travel hydraulic motor 35. Moreover, output of the engine 17 may be transmitted to the generator motor 19 through a power take off (PTO) shaft.

An electric drive system includes a first inverter 21 connected to the generator motor 19 through a power cable, a second inverter 22 connected to the first inverter 21 through a wiring harness, a booster 26 provided between the first inverter 21 and the second inverter 22 through a wiring harness, the capacitor 25 connected to the booster 26 through a contactor 27 (electromagnetic contactor), and the swing motor 23 connected to the second inverter 22 through a power cable. The contactor 27 normally closes an electric circuit formed of the capacitor 25 and the booster 26 to establish an energized state. On the other hand, the hybrid controller C2 is adapted to determine the need to open the electric circuit by detecting a leakage or the like and, when making such determination, the hybrid controller C2 outputs an instruction signal to the contactor 27 to switch the circuit from the energizable state to an interrupted state. The contactor 27 receiving the instruction signal from the hybrid controller C2 then opens the electric circuit.

The swing motor 23 is mechanically connected to the swing machinery 24 as described above. The swing motor 23 is driven by at least one of the power generated in the generator motor 19 and the power stored in the capacitor 25. The swing motor 23 driven by the power supplied from at least one of the generator motor 19 and the capacitor 25 performs a power running operation and causes the upper swing body 5 to swing. Moreover, the swing motor 23 performs a regenerative operation when the upper swing body 5 undergoes swing deceleration, and supplies (charges) power (regenerative energy) generated by the regenerative operation to the capacitor 25. Note that the swing motor 23 includes a speed sensor 55 that detects speed of the swing motor 23. The speed sensor 55 can measure the speed of the swing motor 23 performing the power running operation (swing acceleration) or the regenerative operation (swing deceleration). A signal indicating the speed measured by the speed sensor 55 is input to the hybrid controller C2. A resolver can be used as the speed sensor 55, for example.

The generator motor 19 supplies (charges) the power generated therein to the capacitor 25 as well as supplies power to the swing motor 23 depending on the situation. The generator motor 19 functions as a motor when the output of the engine 17 is insufficient, thereby assisting the output of the engine 17. A switched reluctance (SR) motor is employed as the generator motor 19, for example. Note that a synchronous motor with a permanent magnet instead of the SR motor can also be employed to be able to fulfill the role of supplying power to at least one of the capacitor 25 and the swing motor 23. When the SR motor is employed as the generator motor 19, the SR motor does not require a magnet containing an expensive rare metal and is thus cost effective. A rotor shaft of the generator motor 19 is mechanically connected to the drive shaft 20 of the engine 17. Such structure allows the generator motor 19 to rotate about the rotor shaft thereof by the driving of the engine 17 and generate power. Moreover, a speed sensor 54 is attached to the rotor shaft of the generator motor 19. The speed sensor 54 measures a speed of the generator motor 19, and a signal indicating the speed measured by the speed sensor 54 is input to the hybrid controller C2. A resolver can be employed as the speed sensor 54, for example.

The booster 26 is provided between the generator motor 19 as well as the swing motor 23 and the capacitor 25. The booster 26 boosts the voltage of power (electric charge stored in the capacitor 25) supplied to the generator motor 19 or the swing motor 23 through the first inverter 21 or the second inverter 22. The boosted voltage is applied to the swing motor 23 when the swing motor 23 is to perform the power running operation (swing acceleration) or applied to the generator motor 19 when the output of the engine 17 is to be assisted. The booster 26 also has a role of dropping (stepping down) the voltage when the power generated by the generator motor 19 or the swing motor 23 is charged in the capacitor 25. A booster voltage detection sensor 53 is attached to the wiring harness between the booster 26 and each of the first inverter 21 and the second inverter 22, the booster voltage detection sensor measuring the voltage boosted by the booster 26 or the voltage of power generated by regeneration of the swing motor 23. A signal indicating the voltage measured by the booster voltage detection sensor 53 is input to the hybrid controller C2.

The booster 26 in the present embodiment has a function of boosting or stepping down input DC power and outputting it as DC power. The booster 26 is a booster called a transformer-coupled booster in which a transformer and two inverters are combined, and is an AC link bidirectional DC-DC converter.

(Configuration of Booster)

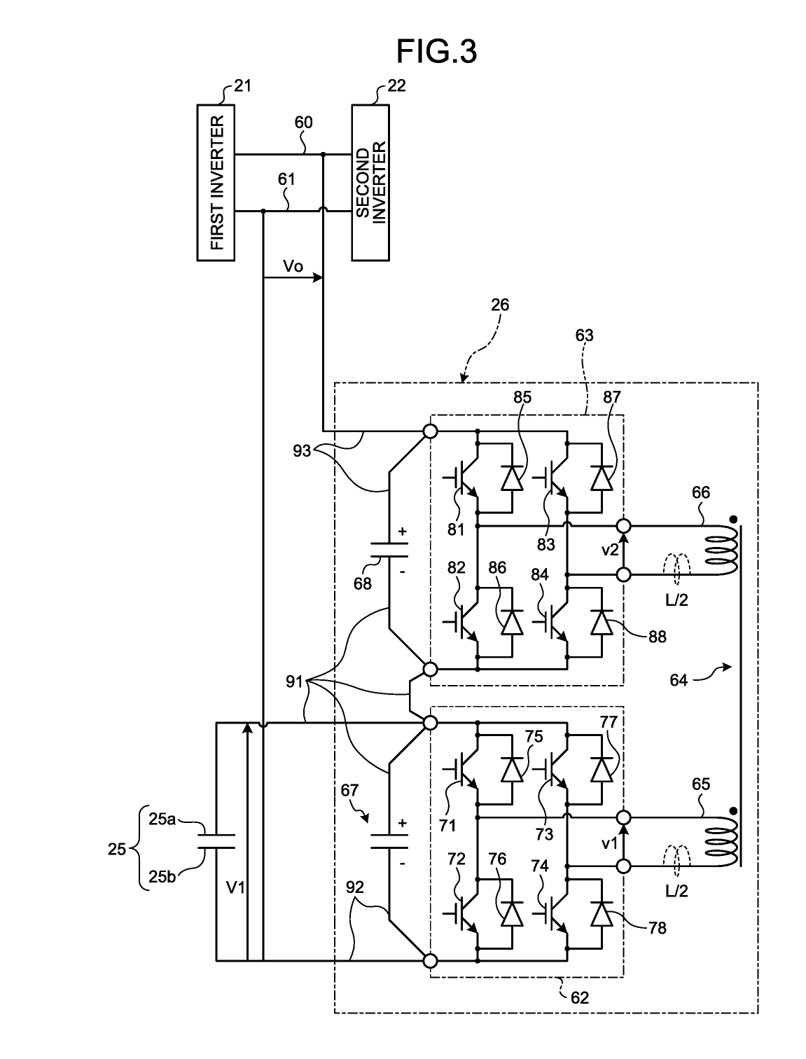

FIG. 3 is a diagram illustrating a configuration of the booster 26. As illustrated in FIG. 3, the booster 26 is configured such that the first inverter 21 and the second inverter 22 are connected via a positive line 60 and a negative line 61 each as a wiring harness. The booster 26 is connected between the positive line 60 and the negative line 61. The booster 26 is configured such that two inverters including a low voltage inverter 62 being a primary inverter and a high voltage inverter 63 being a secondary inverter are AC (Alternating Current) linked and coupled to each other by a transformer 64. Accordingly, the booster 26 is the transformer-coupled booster. Note that in the following description, a winding ratio of a low voltage coil 65 to a high voltage coil 66 of the transformer 64 is set one to one.

The low voltage inverter 62 and the high voltage inverter 63 are electrically connected in series such that a positive electrode of the low voltage inverter 62 and a negative electrode of the high voltage inverter 63 have additive polarity. That is, the booster 26 is connected in parallel to have the same polarity as the first inverter 21.

The low voltage inverter 62 is a bridge circuit including Insulated Gate Bipolar Transistors (IGBTs) 71, 72, 73, and 74 as a plurality of switching elements. The low voltage inverter 62 includes the four IGBTs 71, 72, 73, and 74 establishing bridge connection with the low voltage coil 65 of the transformer 64 as well as diodes 75, 76, 77, and 78 that are connected in parallel with the IGBTs 71, 72, 73, and 74 to have reverse polarity thereto. The bridge connection in this case refers to a structure in which one end of the low voltage coil 65 is connected to an emitter of the IGBT 71 and a collector of the IGBT 72 while another end of the coil is connected to an emitter of the IGBT 73 and a collector of the IGBT 74. The IGBTs 71, 72, 73 and 74 are switched on when a switching signal is applied to a gate, thereby causing a current to flow from the collector to the emitter.

A positive terminal 25a of the capacitor 25 is electrically connected to a collector of the IGBT 71 through a positive line 91. The emitter of the IGBT 71 is electrically connected to the collector of the IGBT 72. An emitter of the IGBT 72 is electrically connected to a negative terminal 25b of the capacitor 25 through a negative line 92. The negative line 92 is connected to the negative line 61.

Likewise, the positive terminal 25a of the capacitor 25 is electrically connected to a collector of the IGBT 73 through the positive line 91. The emitter of the IGBT 73 is electrically connected to the collector of the IGBT 74. An emitter of the IGBT 74 is electrically connected to the negative terminal 25b of the capacitor 25 through the negative line 92.

The emitter of the IGBT 71 (an anode of the diode 75) and the collector of the IGBT 72 (a cathode of the diode 76) are connected to the one terminal of the low voltage coil 65 of the transformer 64, while the emitter of the IGBT 73 (an anode of the diode 77) and the collector of the IGBT 74 (a cathode of the diode 78) are connected to the other terminal of the low voltage coil 65 of the transformer 64.

The high voltage inverter 63 is a bridge circuit including IGBTs 81, 82, 83, and 84 as a plurality of switching elements. The high voltage inverter 63 includes the four IGBTs 81, 82, 83, and 84 establishing bridge connection with the high voltage coil 66 of the transformer 64 as well as diodes 85, 86, 87, and 88 that are connected in parallel with the IGBTs 81, 82, 83, and 84 to have reverse polarity thereto. The bridge connection in this case refers to a structure in which one end of the high voltage coil 66 is connected to an emitter of the IGBT 81 and a collector of the IGBT 82 while another end of the coil is connected to an emitter of the IGBT 83 and a collector of the IGBT 84. The IGBTs 81, 82, 83 and 84 are switched on when a switching signal is applied to a gate, thereby causing a current to flow from the collector to the emitter. The booster 26 includes two bridge circuits, namely the low voltage inverter 62 and the high voltage inverter 63, as described above.

Collectors of the IGBTs 81 and 83 are electrically connected to the positive line 60 of the first inverter 21 through a positive line 93. The emitter of the IGBT 81 is electrically connected to the collector of the IGBT 82. The emitter of the IGBT 83 is electrically connected to the collector of the IGBT 84. Emitters of the IGBTs 82 and 84 are electrically connected to the positive line 91, namely the collectors of the IGBTs 71 and 73 of the low voltage inverter 62.

The emitter of the IGBT 81 (an anode of the diode 85) and the collector of the IGBT 82 (a cathode of the diode 86) are electrically connected to the one terminal of the high voltage coil 66 of the transformer 64, while the emitter of the IGBT 83 (an anode of the diode 87) and the collector of the IGBT 84 (a cathode of the diode 88) are electrically connected to the other terminal of the high voltage coil 66 of the transformer 64.

A capacitor 67 is electrically connected between the positive line 91 to which the collectors of the IGBTs 71 and 73 are connected and the negative line 92 to which the emitters of the IGBTs 72 and 74 are connected. A capacitor 68 is electrically connected between the positive line 93 to which the collectors of the IGBTs 81 and 83 are connected and the positive line 91 to which the emitters of the IGBTs 82 and 84 are connected. The capacitors 67 and 68 are provided to absorb ripple current.

The transformer 64 has leakage inductance of a fixed value L. The leakage inductance can be obtained by adjusting a gap between the low voltage coil 65 and the high voltage coil 66 of the transformer 64. FIG. 3 illustrates a case where the leakage inductance is split between the low voltage coil 65 (L/2) and the high voltage coil 66 (L/2). An operation of the booster 26 will now be described.

(Operation of Booster)

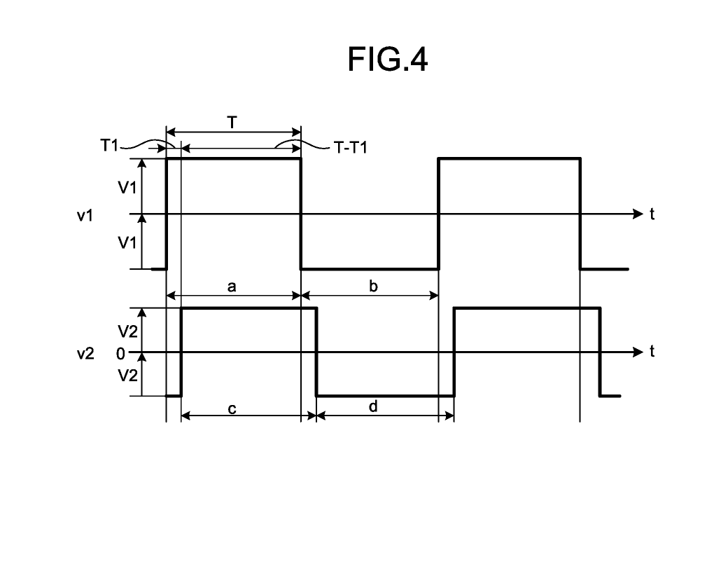

FIG. 4 is a timing chart provided to describe an operation of the booster 26. As illustrated in FIG. 4, voltages (output voltages) v1 and v2 output from the low voltage inverter 62 and the high voltage inverter 63 are square wave voltages with the duty equal to 50%, or a ratio of a high signal to a low signal equal to 1:1. The output voltages v1 and v2 have durations a and c corresponding to the high signal and durations b and d corresponding to the low signal, respectively. For both the output voltages v1 and v2, each of the duration of the high signal and the duration of the low signal equals time t=T. The duty thus equals 50%. The output voltages v1 and v2 are square wave voltages each having a period of 2×T.

The booster 26 adjusts the phase difference between the output voltage v1 of the low voltage inverter 62 and the output voltage v2 of the high voltage inverter 63 to adjust power (booster output) Po and voltage (output voltage) Vo output from the booster 26. The output voltage of the booster 26 corresponds to the voltage of the electric drive system (system voltage) of the hybrid excavator 1. FIG. 4 illustrates the example where a difference in time t=T1 is generated between the output voltage v1 and the output voltage v2. By using this difference, a phase difference D between the output voltage v1 and the output voltage v2 is expressed by expression (1).

D=T1/T (1)

The booster output Po of the booster 26 is expressed by expression (2). In expression (2), Vo denotes the output voltage of the booster 26, V1 denotes a voltage of the capacitor 25, ω denotes an angular frequency equal to 2π/T=2πf, and L denote the leakage inductance of the transformer 64.

Po=n×Vo×V1×D−D²)/(ω×L) (2)

Under control of the hybrid controller C2, the generator motor 19 and the swing motor 23 are subjected to torque control by the first inverter 21 and the second inverter 22, respectively. The second inverter 22 is provided with an ammeter 52 that measures the magnitude of direct current input to the second inverter 22. A signal indicating the current detected by the ammeter 52 is input to the hybrid controller C2. The amount of power (electric charge or capacitance) stored in the capacitor 25 can be managed by using the magnitude of voltage as an indicator. In order to detect the magnitude of voltage of the power stored in the capacitor 25, a capacitor voltage sensor 28 as a storage battery voltage detection unit is provided to a predetermined output terminal of the capacitor 25. A signal indicating the voltage detected by the capacitor voltage sensor 28 is input to the hybrid controller C2. The hybrid controller C2 monitors the amount of charge (amount of power (electric charge or capacitance)) of the capacitor 25 and performs energy management that determines whether to supply (charge) the power generated by the generator motor 19 to the capacitor 25 or to the swing motor 23 (power supplied for a power running action). The booster control unit C21 of the hybrid controller C2 adjusts the phase difference between the output voltage v1 of the low voltage inverter 62 and the output voltage v2 of the high voltage inverter 63 included in the booster 26 such that the output voltage Vo of the booster 26 equals a predetermined voltage.

The capacitor 25 stores at least the power generated by the generator motor 19. The capacitor 25 further stores the power generated by the regenerative operation of the swing motor 23 when the upper swing body 5 undergoes swing deceleration. In the present embodiment, an electric double layer capacitor is employed as the capacitor 25, for example. Another storage battery functioning as a secondary battery such as a lithium ion battery or a nickel-metal hydride battery may be employed instead of the capacitor 25. Moreover, the swing motor 23 is not limited to the permanent magnet synchronous motor employed in this example.

The hydraulic drive system and the electric drive system are driven in response to an operation of the control lever 32 such as a work equipment lever, a travel lever, and a swing lever provided inside the operator cab 6 of the vehicle body 2. When an operator of the hybrid excavator 1 operates the control lever 32 (swing lever) functioning as an operation unit to swing the upper swing body 5, the direction and amount of the operation on the swing lever are detected by a potentiometer or a pilot pressure sensor so that the detected amount of operation is transmitted as an electric signal to the controller C1 and the hybrid controller C2.

Likewise, an electric signal is transmitted to the controller C1 and the hybrid controller C2 when another type of the control lever 32 is operated. In response to the direction and amount of the operation on the swing lever or the direction and amount of the operation on the other control lever 32, the controller C1 and the hybrid controller C2 control the second inverter 22, the booster 26 and the first inverter 21 in order to control transferring of power (perform energy management) such as a rotational operation (power running action or regenerative action) of the swing motor 23, a management of electric energy (charge or discharge control) of the capacitor 25, and a management of electric energy (power generation, assisting engine output, or power running action on the swing motor 23) of the generator motor 19.

In addition to the control lever 32, a monitor device 30 and the key switch 31 are provided inside the operator cab 6. The monitor device 30 is formed of a liquid crystal panel, an operation button and the like. The monitor device 30 may also be a touch panel on which a display function of the liquid crystal panel and a various information inputting function of the operation button are integrated. The monitor device 30 is an information input/output device which has a function of notifying the operator or a service man of information indicating an operating state (state related to engine water temperature, presence/absence of trouble with the hydraulic equipment, or an amount of fuel remaining) of the hybrid excavator 1, as well as a function of performing setting or providing an instruction (output level setting for the engine, speed level setting for the traveling speed, or a capacitor charge release instruction to be described) desired by the operator with respect to the hybrid excavator 1.

The key switch 31 is formed of a key cylinder as a main component. The key switch 31 is configured such that a key is inserted to a key cylinder and turned to start a starter (engine starting motor) attached to the engine 17 and drive the engine 17 (engine start). Moreover, the key switch 31 is configured to give a command to stop the engine (engine stop) by turning the key in a direction opposite to that at the time of the engine start while the engine is running. The key switch 31 is a so-called command output unit that outputs a command to the engine 17 and various electric equipment of the hybrid excavator 1.

When the key is turned (specifically, operated to an off position to be described) to stop the engine 17, fuel supply to the engine 17 as well as supply of electricity (energization) from a battery not illustrated to various electric equipment are cut off, thereby stopping the engine. The key switch 31 can cut off energization from the battery not illustrated to the various electric equipment when the key is turned to the off position (OFF), perform energization from the battery not illustrated to the various electric equipment when the key is turned to an on position (ON), and start the engine by starting the starter not illustrated through the controller C1 when the key is further turned from the on position to a start position (ST). After the engine 17 is started and while the engine 17 is running, the key is at the on position (ON).

The controller C1 is formed of a combination of an arithmetic unit such as a central processing unit (CPU) and a memory (storage). The controller C1 controls the engine 17 and the hydraulic pump 18 on the basis of an instruction signal output from the monitor device 30, an instruction signal output in accordance with the key position of the key switch 31, and an instruction signal (signal indicating the aforementioned amount and direction of the operation) output in accordance with the operation of the control lever 32. The engine 17 is an engine that can be electronically controlled by a common-rail fuel injection device 40. The engine 17 can achieve target engine output when a fuel injection amount is properly controlled by the controller C1, and can run with the engine speed and torque that can be output being set according to a load state of the hybrid excavator 1.

The hybrid controller C2 is formed of a combination of an arithmetic unit such as a CPU and a memory (storage). Under cooperative control with the controller C1, the hybrid controller C2 controls the first inverter 21, the second inverter 22 and the booster 26 as described above and controls transferring of power for the generator motor 19, the swing motor 23 and the capacitor 25. The hybrid controller C2 further acquires a detection value detected by various sensors such as the capacitor voltage sensor 28 and controls the hybrid excavator 1 on the basis of the detection value.

The hybrid controller C2 includes the booster control unit C21. The aforementioned CPU or the like implements a function of the booster control unit C21. Next, there will be described in more detail how the booster control unit C21 of the hybrid controller C2 controls the output voltage of the booster 26.

(Controlling Output Voltage of Booster)

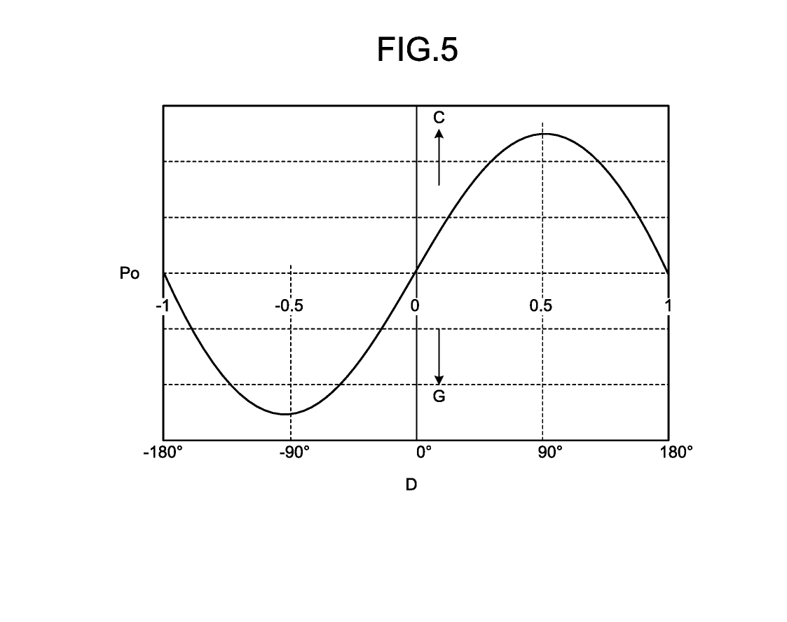

FIG. 5 is a graph illustrating a relationship between booster output and a phase difference. As illustrated in FIG. 5, the booster output Po of the booster 26 at the time of power running (a side corresponding to an arrow C) increases as a phase difference D increases from 0° to 90°, and decreases as the phase difference D increases from 90° to 180°. The booster output Po at the time of regenerating (a side corresponding to an arrow G) increases as the phase difference D increases from −90° to 0°, and decreases as the phase difference D increases from −180° to −90°. The booster control unit C21 of the hybrid controller C2 controls the booster 26 to operate within the range of the phase difference D that is −90° or greater and 90° or less when at least the generator motor 19 is in a power generating state or the swing motor 23 is in an operated state.

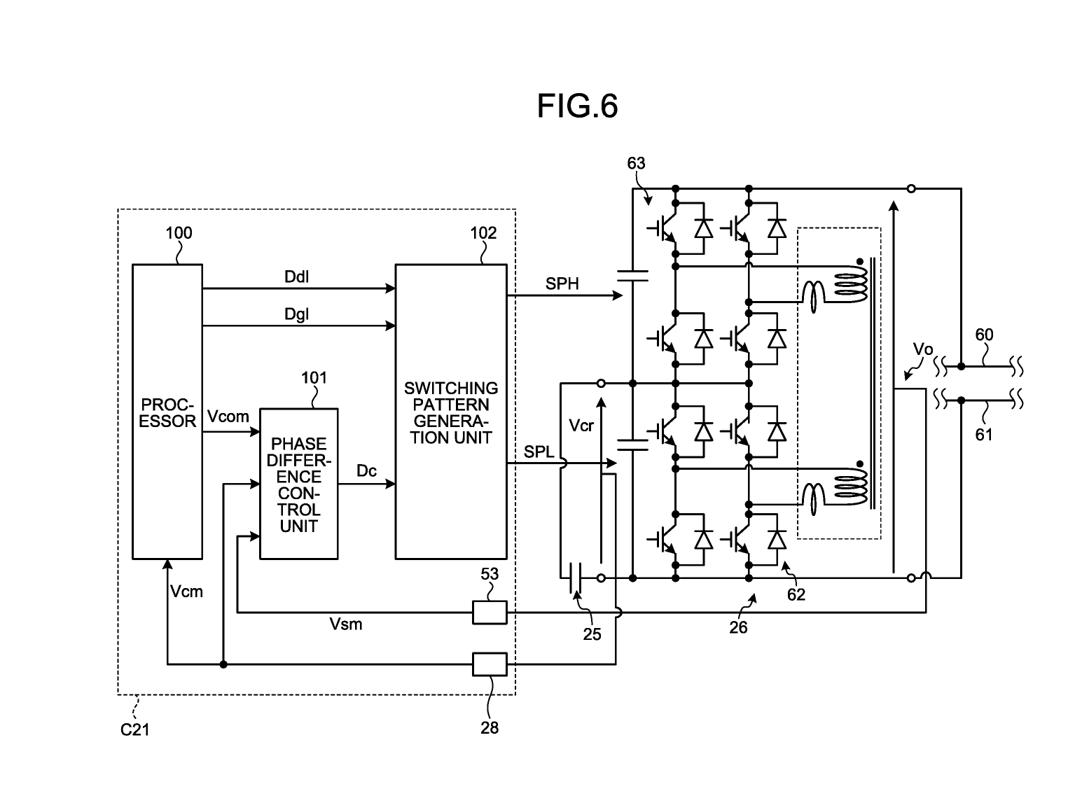

FIG. 6 is a diagram illustrating a configuration of each of the booster control unit C21 included in the hybrid controller C2 and the booster 26. The booster control unit C21 includes a processor 100, a phase difference control unit 101, and a switching pattern generation unit 102. Capacitor voltage Vcm detected by the capacitor voltage sensor 28 is input to the processor 100. The capacitor voltage Vcm corresponds to an inter-terminal voltage (capacitor voltage) Vcr (true value) across the capacitor 25.

The phase difference control unit 101 receives output voltage Vsm of the booster 26 detected by the booster voltage detection sensor 53 as an output voltage detection unit and the capacitor voltage Vcm. The output voltage Vsm corresponds to the output voltage Vo (true value) of the booster 26. The output voltage Vo of the booster 26 is a voltage across the positive line 60 and the negative line 61 and is the output voltage or input voltage of the first inverter 21 and the second inverter 22 illustrated in FIGS. 2 and 3.

The processor 100 of the booster control unit C21 outputs an output voltage command value Vcom specifying the output voltage of the booster 26 to the phase difference control unit 101. The processor 100 outputs to the switching pattern generation unit 102 a limit value Ddl of the phase difference D at the time of power running and a limit value Dgl of the phase difference D at the time of regenerating. The former equals +90°, and the latter equals −90°. The switching pattern generation unit 102 controls the low voltage inverter 62 and the high voltage inverter 63 of the booster 26 such that the phase difference D of the booster 26 does not exceed the limit values Ddl and Dgl.

The phase difference control unit 101 obtains the phase difference D of the booster 26 such that a difference between the output voltage command value Vcom and the output voltage Vsm equals zero, and outputs the obtained phase difference D as a control phase difference Dc to the switching pattern generation unit 102. The switching pattern generation unit 102 generates switching patterns SPL and SPH to turn ON/OFF each switching element included in the low voltage inverter 62 and the high voltage inverter 63, respectively. The switching pattern generation unit 102 supplies, to the low voltage inverter 62 and the high voltage inverter 63, the switching patterns SPL and SPH generated such that the phase difference D of the booster 26 equals the control phase difference Dc, and turns ON/OFF the switching element included in the corresponding inverter. That is, the switching pattern generation unit 102 is driven such that the phase difference D of the booster 26 equals the control phase difference Dc. As a result, the output voltage Vo of the booster 26 equals the output voltage command value Vcom output from the processor 100. The booster control unit C21 thus performs feedback control on the booster 26 such that the output voltage Vo of the booster 26 equals the output voltage command value Vcom.

(Phase Difference Control Unit)

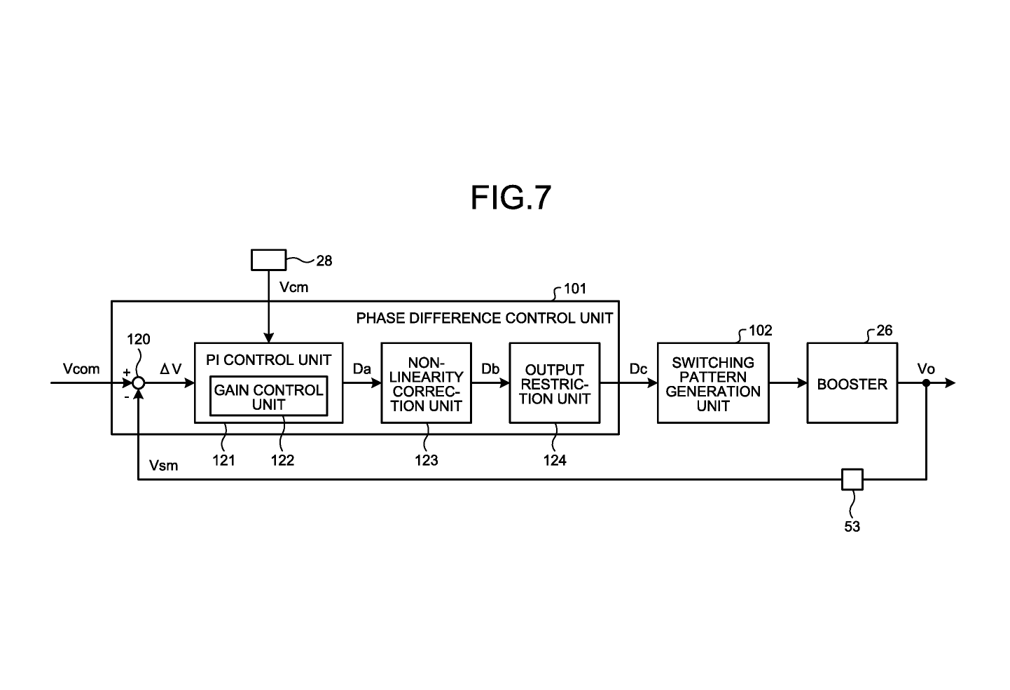

FIG. 7 is a block diagram including a detailed configuration of the phase difference control unit 101. As illustrated in FIG. 7, the phase difference control unit 101 includes a differential unit 120, a PI control unit 121 including a gain control unit 122, a non-linearity correction unit 123, and an output restriction unit 124. The differential unit 120 calculates a differential value ΔV between the output voltage command value Vcom and the output voltage Vsm, and outputs the differential value ΔV to the PI control unit 121. The PI control unit 121 outputs a control phase difference Da corresponding to the differential value ΔV to the non-linearity correction unit 123 such that the differential value ΔV equals zero.

(Gain Control Unit)

At the time, on the basis of the capacitor voltage dependency of the input-output characteristic representing the booster output Po with respect to the phase difference of the booster 26, the gain control unit 122 corrects a control gain of the PI control unit 121 according to the capacitor voltage Vcm detected by the capacitor voltage sensor 28 and causes the control phase difference Da to be output to the side of the booster 26 such that the booster output Po has the control gain uniquely determined by the control phase difference Da independently of the capacitor voltage V1.

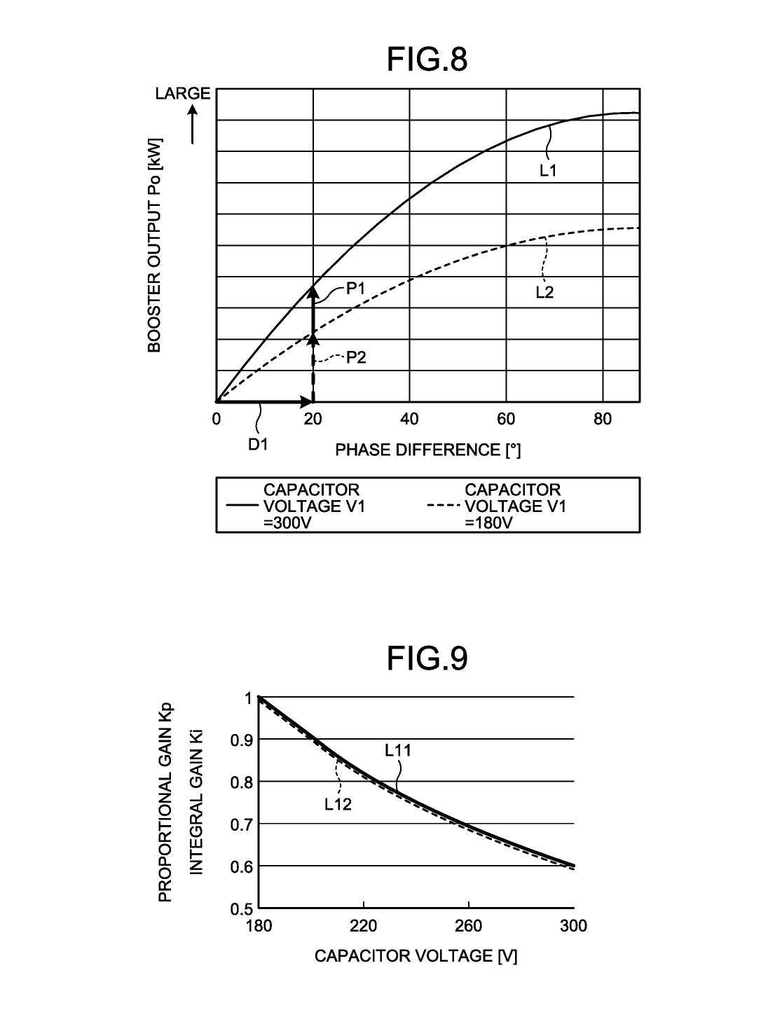

As illustrated in FIG. 8, the input-output characteristic representing the booster output Po with respect to the phase difference of the booster 26 is different when the capacitor voltage V1 is different; that is, the capacitor voltages 300 V and 180 V correspond to input-output characteristics L1 and L2, respectively. In other words, the input-output characteristic has the capacitor voltage dependency. As a result, for the same phase difference D1 (=20°) being input, the booster output increases by P1 (=37 kW) when the capacitor voltage V1 equals 300 V, whereas the booster output increases by P2 (=22 kW) which is less than the booster output P1 (=37 kW) when the capacitor voltage V1 equals 180 V. That is, even the same phase difference causes a difference in the control gain of the booster output depending on the value of the capacitor voltage V1.

Here, when the control gain is determined to be small assuming that the capacitor voltage V1 is high (such as when the capacitor voltage V1 equals 300 V), the control gain of the booster is small when the capacitor voltage V1 is low (such as when the capacitor voltage equals 180 V) so that followability of the output voltage Vo with respect to the output voltage command value Vcom is degraded. On the other hand, when the control gain is determined to be large assuming that the capacitor voltage V1 is low, the control gain of the booster is large when the capacitor voltage V1 is high so that hunting or oscillation can possibly occur.

Now, in order to eliminate the capacitor voltage dependency of the input-output characteristic involved in voltage control on the output voltage by the control phase difference, the gain control unit 122 of the present embodiment is configured such that the booster output Po has the control gain uniquely determined by the input control phase difference independently of the capacitor voltage V1. That is, for the same phase difference, the control gain is corrected according to the capacitor voltage V1 in order for the control gain to not change even when the capacitor voltage V1 changes.

Specifically, as illustrated in FIG. 9, the control gain is corrected to have correction characteristics L11 and L12 with which each of a proportional gain Kp and an integral gain Ki decreases as the capacitor voltage V1 (Vcm) increases.

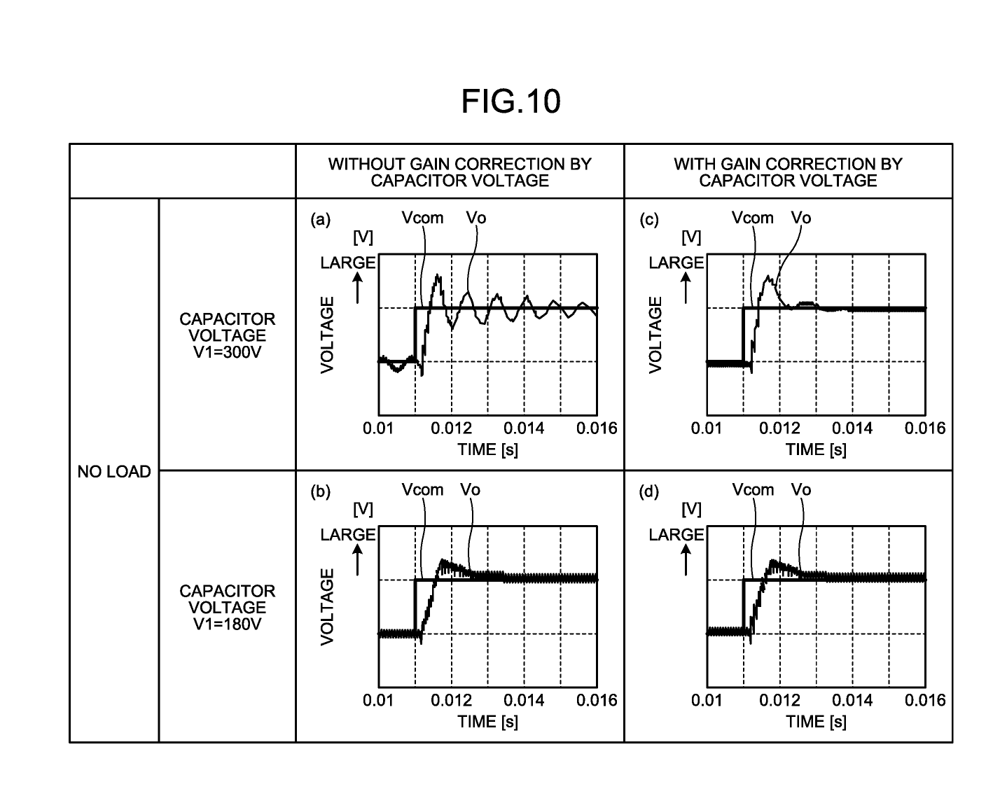

FIG. 10 is a diagram illustrating an effect when the gain control unit 122 performs gain correction by the capacitor voltage with respect to a stepwise change of the output voltage command value Vcom. As illustrated in FIGS. 10 (a) and (b), when the gain correction by the capacitor voltage V1 (Vcm) is not performed, the output voltage Vo is stable (FIG. 10 (b)) with the control gain being set by the input-output characteristic L2 for the low capacitor voltage V1 (V1=180 V), whereas the output voltage Vo experiences hunting (FIG. 10 (a)) with the control gain being set by the input-output characteristic L1 for the high capacitor voltage V1 (V1=300 V). On the other hand, as illustrated in FIGS. 10 (c) and (d), the output voltage Vo can be controlled stably for both the low capacitor voltage V1 (V1=180 V) and the high capacitor voltage V1 (V1=300 V) when the gain control unit 122 performs the gain correction by the capacitor voltage V1 (Vcm). Note that when the gain control unit 122 performs the gain correction by the capacitor voltage V1 (Vcm), the dependency of the control gain on the capacitor voltage V1 is eliminated so that followability with respect to the output voltage command value is not degraded even when the capacitor voltage is low.

(Non-Linearity Correction Unit)

The non-linearity correction unit 123 corrects the control phase difference Da being input and outputs a corrected control phase difference Db to the output restriction unit 124 such that non-linearity of the input-output characteristic representing the booster output Po with respect to the phase difference of the booster 26 becomes linear.

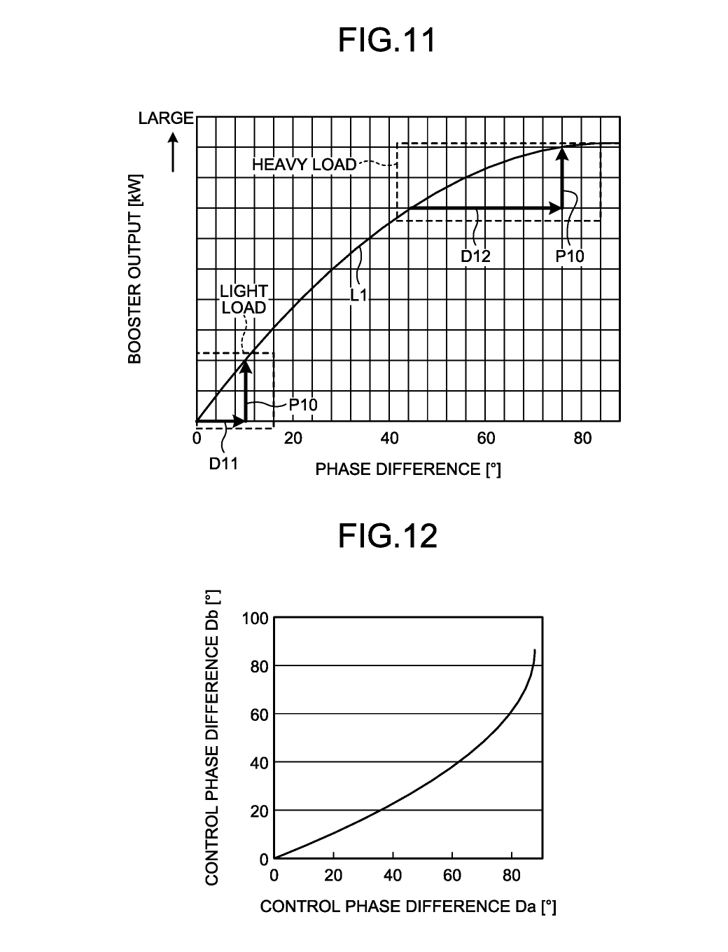

FIG. 11 illustrates the input-output characteristic L1 representing the booster output Po with respect to the phase difference of the booster 26 when the capacitor voltage V1 equals 300 V. As illustrated in FIG. 11, the booster output Po with respect to the phase difference is non-linear in the input-output characteristic L1. That is, according to the input-output characteristic L1, a rate of increase of the booster output decreases as the phase difference increases. This is because, as expressed in expression (2), the booster output Po is a function of (D−D²) as the phase difference D. Accordingly, a gain of a booster output P10 with respect to an input phase difference D11 at the time of a light load is small compared to a gain of the booster output P10 with respect to an input phase difference D12 at the time of a heavy load. In other words, in order to obtain the same increase in the booster output P10, the input phase difference needs to be changed by D11 (=10°) at the time of the light load, whereas the input phase difference needs to be changed by D12 (=32°) at the time of the heavy load.

Where the control gain of the booster varies between the small phase difference (at the time of the light load) and the large phase difference (at the time of the heavy load) as described above, a large phase difference results in a small control gain of the booster when the control gain is determined assuming a small phase difference (a large control gain of the booster), for example, so that followability of the output voltage Vo with respect to the output voltage command value Vcom is degraded. On the other hand, when the control gain is determined assuming a large phase difference (a small control gain of the booster), a small phase difference results in a large control gain of the booster so that hunting or oscillation can possibly occur.

Accordingly, in the present embodiment, the non-linearity correction unit 123 cancels out the variation in the control gain that varies according to the magnitude of the phase difference to perform correction such that the control gain of the booster does not change regardless of the magnitude of the phase difference. Specifically, as illustrated in a correction table in FIG. 12, the non-linearity correction unit performs phase difference correction of increasing the control phase difference Db being output as the input control phase difference Da increases to thus perform the correction such that the control gain does not change according to the magnitude of the phase difference.

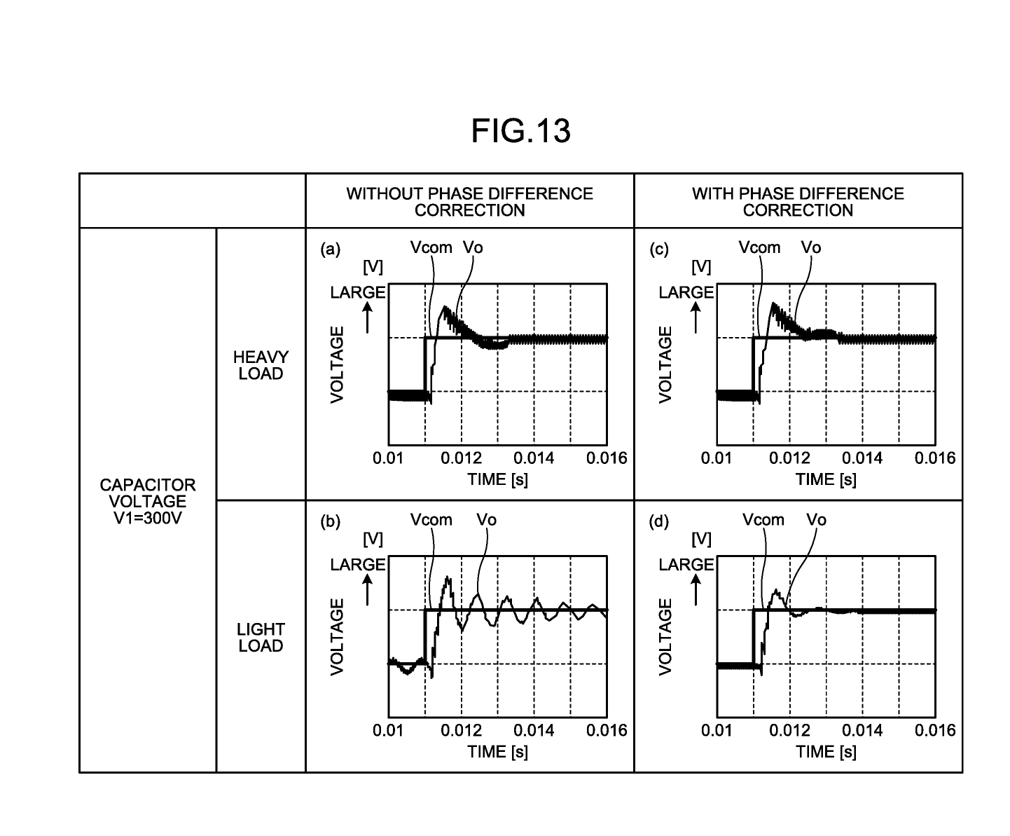

FIG. 13 is a diagram illustrating an effect when the non-linearity correction unit 123 performs the gain correction with respect to a stepwise change of the output voltage command value Vcom. As illustrated in FIG. 13 (b), when the phase difference correction is not performed with the capacitor voltage V1 being 300 V, the output voltage Vo experiences hunting at the time of the light load at which time the phase difference is small. On the other hand, when the non-linearity correction unit 123 performs the phase difference correction as illustrated in FIGS. 13 (c) and (d), the output voltage Vo can be controlled stably both at the time of the light load at which time the phase difference is small (FIG. 13 (d)) and at the time of the heavy load at which time the phase difference is large (FIG. 13 (c)). Note that the dependency of the control gain by the phase difference is eliminated when the phase difference correction is performed by the non-linearity correction unit 123, whereby the followability with respect to the output voltage command value is not degraded even when the phase difference is large.

(Output Restriction Unit)

The output restriction unit 124 restricts the input control phase difference Db to a predetermined value ΔD or less for each control period, and outputs a control phase difference Dc under the restriction to the switching pattern generation unit 102. The phase difference of 22.5° with respect to the maximum phase difference is set to the predetermined value ΔD, for example.

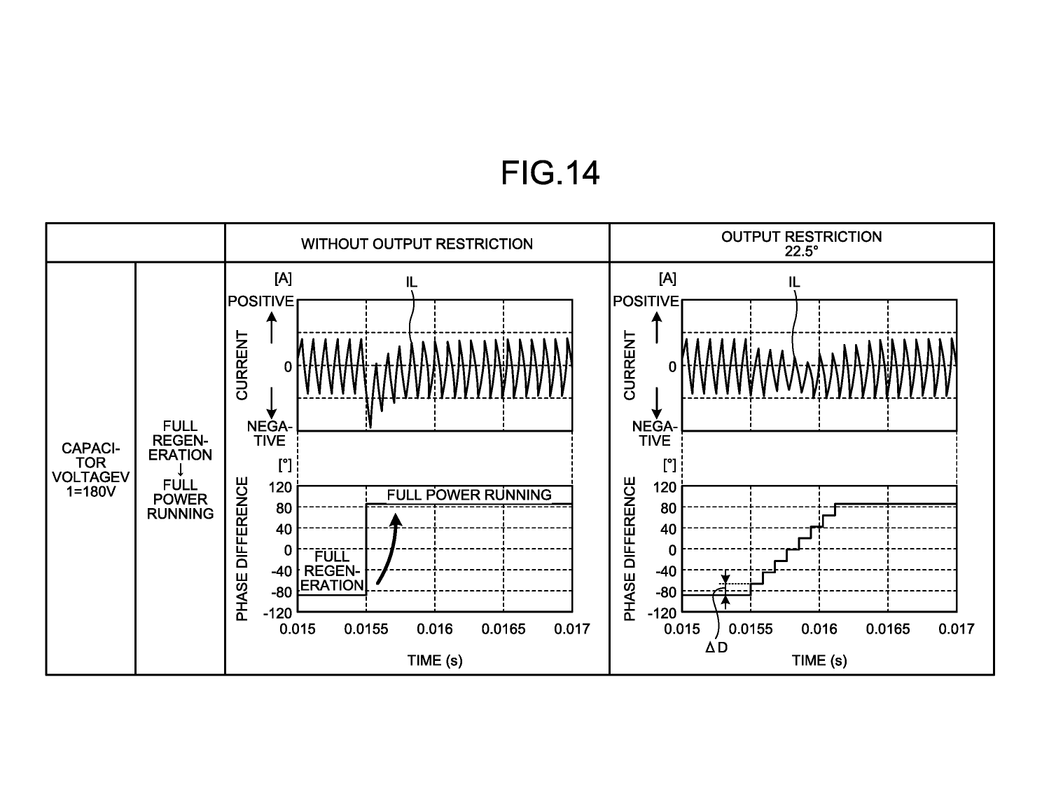

FIG. 14 illustrates a case where the output restriction on the phase difference is not performed by the output restriction unit 124, in which case the phase difference changes instantaneously by approximately 180° in a single control period when there is performed an instantaneous change in the operation from full regeneration to full power running. In this case, a large current may occur transiently such as in the example illustrated in FIG. 14 where a peak value of current IL fed to a transformer is 955 A, and the overcurrent can possibly break a switching device (IGBT).

On the other hand, when the output restriction on the phase difference is performed by the output restriction unit 124 and there is performed a shift in the operation from full regeneration to full power running, a variation of the phase difference allowed in a single control period equals the predetermined value ΔD or less, so that the phase difference is changed by the predetermined value ΔD or less stepwise in every control period and that the peak value of the current IL fed to the transformer can be reduced to 534 A as illustrated in FIG. 14. This can prevent the occurrence of the large transient current.

Note that the aforementioned phase difference control unit 101 preferably has a software configuration, not a hardware configuration. The PI control unit 121 including the gain control unit 122, the non-linearity correction unit 123 and the output restriction unit 124 are preferably configured by software. At this time, it is preferred that the gain control unit 122 uses the correction table illustrated in FIG. 9 while the non-linearity correction unit 123 uses the correction table illustrated in FIG. 12. Moreover, a change in setting can easily be performed on the predetermined value ΔD for the output restriction unit 124 as it is configured by software.

Furthermore, an embodiment may be implemented such that one or more of the aforementioned gain control unit 122, non-linearity correction unit 123 and output restriction unit 124 are combined. The booster may include only the gain control unit 122 or only the gain control unit 122 and the non-linearity correction unit 123, for example.

### REFERENCE SIGNS LIST

1 HYBRID EXCAVATOR
2 VEHICLE BODY
3 WORK EQUIPMENT
4 LOWER TRAVELING BODY
4A TRAVEL UNIT
4B CRAWLER BELT
5 UPPER SWING BODY
6 OPERATOR CAB
7 FUEL TANK
8 HYDRAULIC FLUID TANK
9 ENGINE ROOM
10 COUNTER WEIGHT
11 BOOM
12 ARM
13 BUCKET
14 BOOM HYDRAULIC CYLINDER
15 ARM HYDRAULIC CYLINDER
16 BUCKET HYDRAULIC CYLINDER
17 ENGINE
18a SWASH PLATE
18 HYDRAULIC PUMP
19 GENERATOR MOTOR
20 DRIVE SHAFT
21 FIRST INVERTER
22 SECOND INVERTER
23 SWING MOTOR
24 SWING MACHINERY
25 CAPACITOR
25a POSITIVE TERMINAL
25b NEGATIVE TERMINAL
26 BOOSTER
27 CONTACTOR
28 CAPACITOR VOLTAGE SENSOR
30 MONITOR DEVICE
31 KEY SWITCH
32 CONTROL LEVER
33 CONTROL VALVE
34 RIGHT TRAVEL HYDRAULIC MOTOR
35 LEFT TRAVEL HYDRAULIC MOTOR
40 FUEL INJECTION DEVICE
41 SPEED SENSOR
52 AMMETER
53 BOOSTER VOLTAGE DETECTION SENSOR
54, 55 SPEED SENSOR
60 POSITIVE LINE
61 NEGATIVE LINE
62 LOW VOLTAGE INVERTER
63 HIGH VOLTAGE INVERTER
64 TRANSFORMER
65 LOW VOLTAGE COIL
66 HIGH VOLTAGE COIL
67, 68 CAPACITOR
75 to 78, 85 to 88 DIODE
91, 93 POSITIVE LINE
92 NEGATIVE LINE
100 PROCESSOR
101 PHASE DIFFERENCE CONTROL UNIT
102 SWITCHING PATTERN GENERATION UNIT
120 DIFFERENTIAL UNIT
121 PI CONTROL UNIT
122 GAIN CONTROL UNIT
123 NON-LINEARITY CORRECTION UNIT
124 OUTPUT RESTRICTION UNIT
C1 CONTROLLER
C2 HYBRID CONTROLLER
C21 BOOSTER CONTROL UNIT
D, D1 PHASE DIFFERENCE
D11, D12 INPUT PHASE DIFFERENCE
Da, Db, Dc CONTROL PHASE DIFFERENCE
Ki INTEGRAL GAIN
Kp PROPORTIONAL GAIN
L1, L2 INPUT-OUTPUT CHARACTERISTIC
L11, L12 CORRECTION CHARACTERISTIC
P1, P2, P10, Po BOOSTER OUTPUT
Po BOOSTER OUTPUT
SPL, SPH SWITCHING PATTERN
V1, Vcm CAPACITOR VOLTAGE
v1,v2, Vo,Vsm OUTPUT VOLTAGE
Vcom OUTPUT VOLTAGE COMMAND VALUE
ΔD PREDETERMINED VALUE
ΔV DIFFERENTIAL VALUE

1. A booster control device comprising:
an output voltage detection unit that detects output voltage of a booster which is a transformer-coupled DC-DC converter in which two bridge circuits each having a plurality of switching elements are coupled to each other by a transformer, is provided between an inverter connected to a rotating electrical machinery and a storage battery supplying power to the rotating electrical machinery, and changes the output voltage according to a phase difference between voltages output by each of the bridge circuits;
a storage battery voltage detection unit that detects storage battery voltage across the storage battery; and
a booster control unit that performs feedback control on the output voltage of the booster in order for a difference between an output voltage command value to the booster and detected output voltage detected by the output voltage detection unit to be equal to zero, wherein
the booster control unit includes a gain control unit that corrects a control gain according to the storage battery voltage detected by the storage battery voltage detection unit on the basis of storage battery voltage dependency of an input-output characteristic representing booster output with respect to a phase difference of the booster, in order for the booster output to have the control gain uniquely determined by the phase difference independently of the storage battery voltage and outputs a control phase difference to the booster.

2. The booster control device according to claim 1, wherein the booster control unit includes a non-linearity correction unit that corrects the control phase difference in order for non-linearity of the input-output characteristic representing the booster output with respect to the phase difference of the booster to be linear.

3. The booster control device according to claim 1, wherein the booster control unit includes an output restriction unit that restricts a variation in output of the control phase difference to a predetermined value or less in each control period.

4. The booster control device according to claim 1, wherein the storage battery is a capacitor.

5. A method of controlling voltage of a booster control device comprising: an output voltage detection unit that detects output voltage of a booster which is a transformer-coupled DC-DC converter in which two bridge circuits each having a plurality of switching elements are coupled to each other by a transformer, is provided between an inverter connected to a rotating electrical machinery and a storage battery supplying power to the rotating electrical machinery, and changes the output voltage according to a phase difference between voltages output by each of the bridge circuits; a storage battery voltage detection unit that detects storage battery voltage across the storage battery; and a booster control unit that performs feedback control on the output voltage of the booster in order for a difference between an output voltage command value to the booster and detected output voltage detected by the output voltage detection unit to be equal to zero, wherein
the booster control unit corrects a control gain according to the storage battery voltage detected by the storage battery voltage detection unit on the basis of storage battery voltage dependency of an input-output characteristic representing booster output with respect to a phase difference of the booster, in order for the booster output to have the control gain uniquely determined by the phase difference independently of the storage battery voltage and outputs a control phase difference to the booster.

6. The method of controlling voltage of a booster control device according to claim 5, wherein the booster control unit corrects the control phase difference in order for non-linearity of the input-output characteristic representing the booster output with respect to the phase difference of the booster to be linear.

7. The method of controlling voltage of a booster control device according to claim 5, wherein the booster control unit restricts a variation in output of the control phase difference to a predetermined value or less in each control period.
